(19) United States
(12) Patent Application Publication
(10) Pub. No.: US 2008/0276868 A1
(43) Pub. Date: Nov. 13, 2008

(54) RIGID RF TRANSMISSION LINE WITH EASY REMOVAL SECTION

(76) Inventors: Carl A. Sorensen, Morgan Hill, CA (US); John M. White, Hayward, CA (US); Kim Neill, San Jose, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 12/039,616

(22) Filed: Feb. 28, 2008

Related U.S. Application Data
(60) Provisional application No. 60/892,118, filed on Feb. 28, 2007.

(51) Int. Cl. C23C 16/453; H01B 7/17

(52) U.S. Cl. 118/723 I; 174/102 R

(57) ABSTRACT

An RF feed for a processing apparatus is disclosed. Coupling an RF generator to an RF matching network by a rigid RF feed lessens the amount of power that is lost during transmission from the generator to the matching network. The rigid RF feed comprises an inverted J shaped section that decouples the generator from the matching network whenever servicing the chamber is necessary. The J shape section has two parallel portions coupled together by a perpendicular portion. The J shaped section may be removed as a one piece assembly by uncoupling the J shaped section at a location disposed near the top of the chamber and a location near the floor of the chamber. The connections between the J shaped section and the remainder of the RF feed face the same direction to ensure easy coupling and decoupling without twisting and/or bending any portion of the rigid RF feed.

### CROSS-REFERENCE TO RELATED APPLICATIONS

This application claims benefit of U.S. Provisional Patent Application Ser. No. 60/892,118 (APPM/11906L), entitled “Rigid RF Transmission Line with Easy Removal Section”, filed Feb. 28, 2007, which is herein incorporated by reference.

### BACKGROUND OF THE INVENTION

1. Field of the Invention

Embodiments of the present invention generally relate to a rigid radio frequency (RF) feed from an RF generator to a matching network.

2. Description of the Related Art

Large area substrates may be used to fabricate such items as flat panel displays and solar panels. These substrates may exceed 2 square meters in surface area. One deposition method used to deposit material onto large area substrates is plasma enhanced chemical vapor deposition (PECVD). In a PECVD chamber, RF power may be supplied to the chamber through an RF matching network. The RF power may be generated remove from the PECVD chamber at an RF generator. Thus, there is a need in the art for an RF feed to deliver RF power from an RF generator to an RF matching network.

### SUMMARY OF THE INVENTION

The present invention generally relates to an RF feed for a processing apparatus. Coupling an RF generator to an RF matching network by a rigid RF feed lessens the amount of power that is lost during transmission from the generator to the matching network. The rigid RF feed comprises an inverted J shaped section that easily decouples the generator from the matching network whenever servicing the chamber is necessary. The J shape section has two parallel portions coupled together by a perpendicular portion. The J shaped section may be removed as a one-piece assembly by uncoupling the J shaped section at two locations. One location is disposed near the top of the chamber and the other location is near the floor of the chamber. The connections between the J shaped section and the remainder of the RF feed face the same direction to ensure easy coupling and decoupling without twisting and/or bending any portion of the rigid RF feed.

In one embodiment, a power source for a processing chamber is disclosed. The power source comprises a power generator, a power input coupled with the processing chamber, and a rigid feed coupling the power generator to the power input. The feed line may have at least one inverted J shaped portion.

In another embodiment, a plasma apparatus is disclosed. The apparatus comprises a lid assembly, an RF matching network disposed on the lid assembly, an RF generator, and a rigid RF feed line coupled between the RF matching network and the RF generator.

In another embodiment, a method of connecting a power supply to a processing chamber is disclosed. The method may comprise lowering a rigid RF feed line into contact with both a power supply and a matching network. The RF feed may comprise two substantially parallel portions and a portion substantially perpendicular to the two substantially parallel portions. The method may also comprise connecting a first end of the rigid RF feed to a power supply and connecting a second end of the rigid RF feed to a matching network.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a perspective view of a system having a rigid RF feed coupled to one of the processing chambers according to one embodiment of the invention.

FIG. 2 is a side view of the processing chamber of FIG. 1 having the rigid RF feed coupled thereto.

FIG. 3 is a backside view of the processing chamber of FIG. 1 having the rigid RF feed coupled between an RF generator and an RF matching network.

FIG. 4 is a perspective view of a rigid RF feed coupled between a matching network and an RF generator according to one embodiment of the invention.

FIG. 5 is a schematic view of the inverted J section of the RF feed of FIG. 4 disconnected according to one embodiment of the invention.

FIG. 6A is a cross sectional view of a coupling for a rigid RF feed according to one embodiment of the invention.

FIG. 6B is a cross sectional view of the coupling shown in FIG. 6A with the coupling uncoupled.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The present invention relates to an RF feed for a processing apparatus. While the invention will be described below in relation to a PECVD chamber available from AKT, a subsidiary of Applied Materials, Inc., Santa Clara, Calif., it is to be understood that the invention is equally applicable to any chamber that may require an RF feed to supply power to a matching network from an RF generator including physical vapor deposition (PVD) chambers. It is also to be understood that the invention described below is equally applicable to PECVD chambers and other chambers made by other vendors.

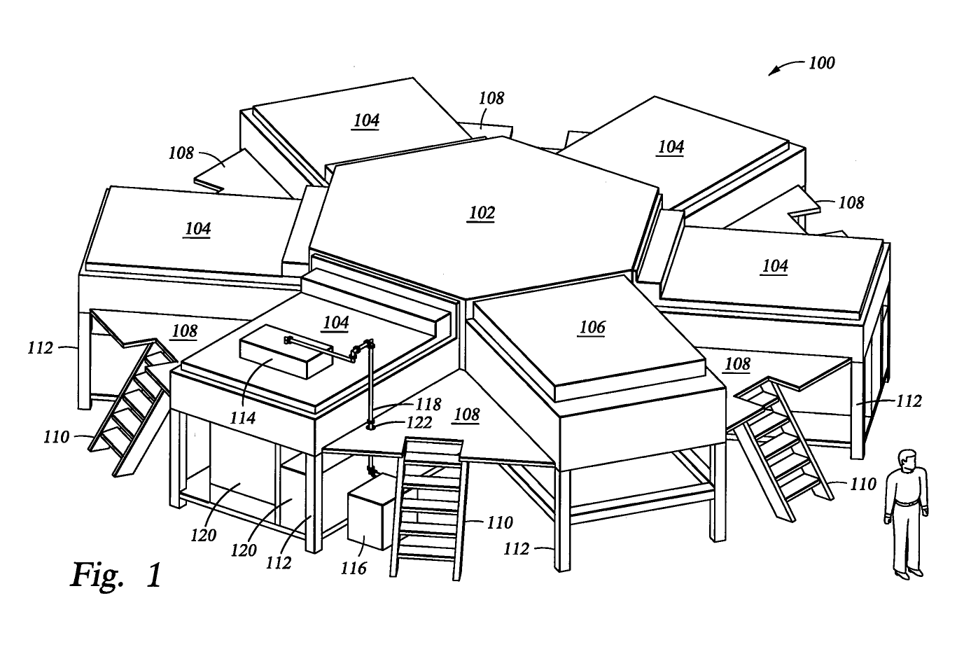

FIG. 1 is a perspective view of a processing system 100 having a rigid RF feed coupled to one of the processing chambers 104 according to one embodiment of the invention. The processing system 100 shown in FIG. 1 is an example of a cluster tool in which a plurality of processing chambers 104 surround a central transfer chamber 102. One or more load lock chambers 106 may also be coupled to the transfer chamber 102. Each of the processing chambers 104 and the load lock chamber 106 may be elevated off of the ground by a support frame 112 that matches the elevation of the slots of the transfer chamber 102 to the slots of the processing chambers 104 and the load lock chamber 106. The slots are the openings through which substrates pass when they are moved between chambers 102, 104, 106.

Adjacent processing chambers 104 and load lock chambers 106 may be separated by platforms 108. A platform permits a technician to access the top of the processing chambers 104 and the load lock chamber 106. A platform 108 may be disposed between each adjacent chamber 104, 106 and stands at about one half the height of the processing chamber 104. The platforms 108 may be accessed by a ladder 110 or staircase or any other suitable means for accessing an elevated surface.

The processing chambers 104 may be any type processing chamber such as a PECVD chamber, a PVD chamber, or any other suitable processing chamber. The processing chambers 104 may be used to process any type of substrate such as a semiconductor substrate, a flat panel display substrate, a solar panel substrate, etc. The controllers 120 necessary for controlling the processes performed in the processing chambers 104 may be disposed under the processing chambers 104 and within the support frame 112.

For some processes, an RF power may need to be applied. In some situations, the RF power may be used to generate a plasma. In other situations, RF power may be used for heating. When RF power is applied to generate a plasma, the RF power may be generated in an RF generator 116 and pass through an RF feed 118 to a matching network 114. The RF generator 116 may be disposed below the platform 108. By disposing the RF generator 116 under the platform 108, the distance that the RF power must travel from the RF generator 116 to the RF matching network 114 is as short as possible. By having as short a distance as possible between the RF generator 116 and the matching network 114, the amount of power lost during transmission from the RF generator 116 to the RF matching network 114 may be minimized. To ensure as short as distance as possible is utilized, the RF feed 118 may be positioned to travel through an opening 122 within the platform 108. In one embodiment length of the RF feed 118 between the RF generator 116 and the RF matching network 114 is about twenty feet.

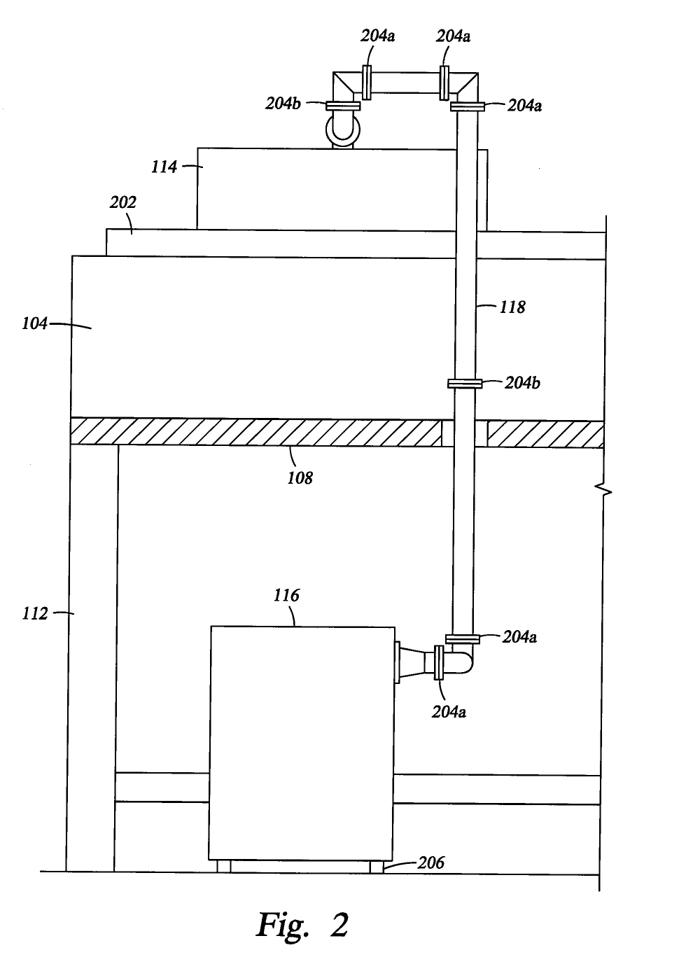

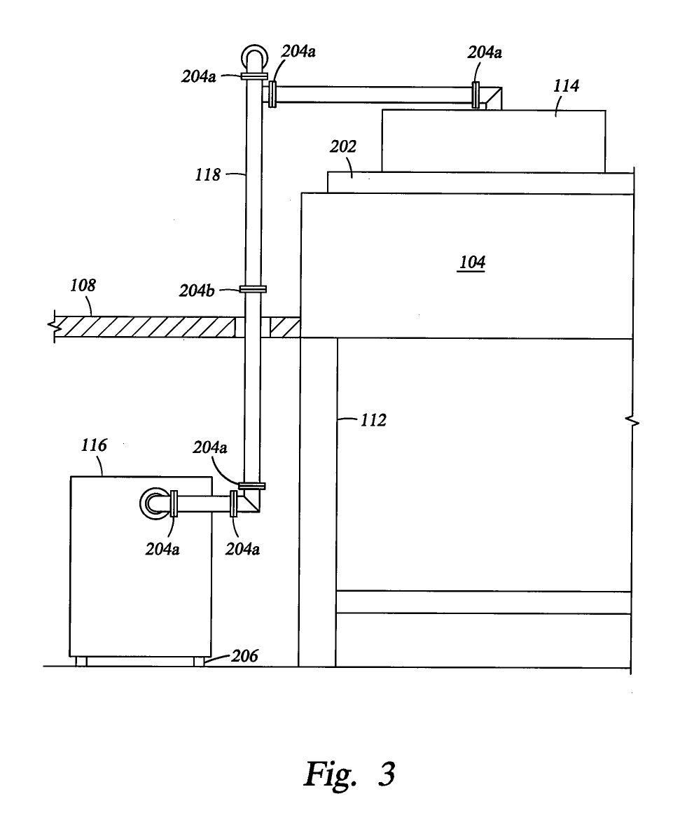

FIG. 2 is a side view of the processing chamber 104 of FIG. 1 having the rigid RF feed 118 coupled thereto. FIG. 3 is a backside view of the processing chamber of FIG. 1 having the rigid RF feed coupled between an RF generator 116 and an RF matching network 114. The RF generator 116 may be grounded through legs 206. The RF feed 118 has a plurality of couplings 204a along the length of the RF feed 118. In one embodiment, the couplings 204a may be fastened together by a one-way coupling mechanism. The one way coupling mechanism may be any known coupling mechanism that permits two items, in this embodiment two RF feed sections, to be joined together while making it difficult, if not impossible, to uncouple the items. The couplings 204a are one-way coupling mechanisms to discourage a technician from uncoupling the RF feed 118 at the couplings 204a.

Couplings 204b, on the other hand, may be fastened together by a coupling mechanism that permits easy coupling and uncoupling. In one embodiment, the couplings 204b may comprise a nut and bolt assembly. The couplings 204b encourage a technician to uncouple the RF feed 118 and the couplings 204b rather than at the one way couplings 204a.

One of the couplings 204b may be disposed just above the level of the platform 108. In one embodiment, the coupling 204b may be about five inches above the platform 108. The other coupling 204b may be disposed above the lid 202 of the processing chamber 104. As may be seen in FIG. 2, the portion of the RF feed 118 between the couplings 204b is substantially the shape of an inverted “J”. FIG. 3 shows that the vertical portions of the RF feed 188 are aligned along parallel axis so that whenever couplings 204b are uncoupled, the inverted “J” portion of the RF feed 118 may be removed by raising the inverted “J” portion. By simply raising the inverted “J” portion of the RF feed 118, no bending of the RF feed 118 is necessary. Hence, the RF feed 118 may be a rigid structure that is not substantially deformable. Conversely, if couplings 204a are uncoupled, there is an increased likelihood of bending and hence, breaking of the RF feed 118. When the couplings 204b are uncoupled and the inverted “J” portion is removed, the lid 202 of the processing chamber 104 may be removed without damaging the RF feed 118.

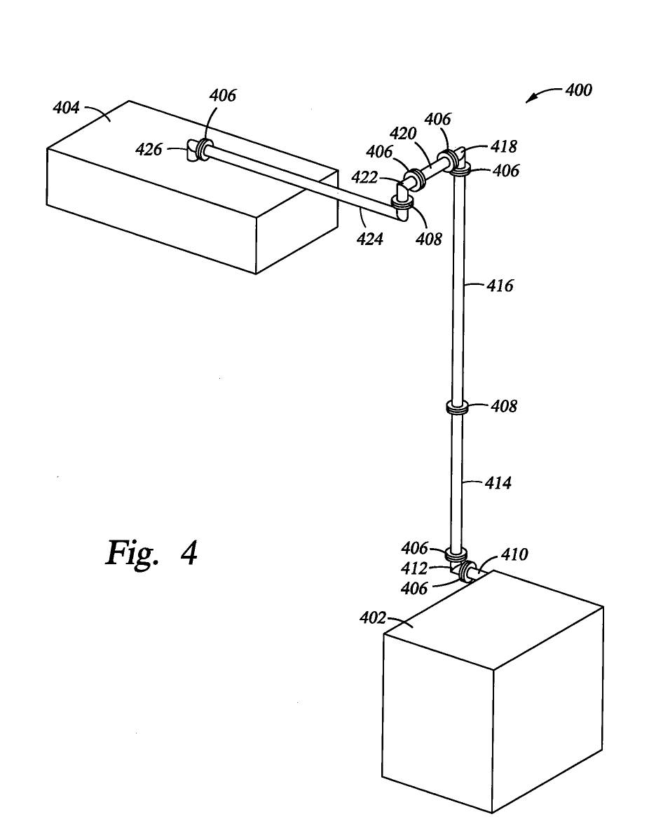

FIG. 4 is a perspective view of a rigid RF feed coupled between a matching network 404 and an RF generator 402 according to one embodiment of the invention. The system 400 comprises a plurality of tubes 410, 412, 414, 416, 418, 420, 422, 424, 426 coupled together by couplings 406, 408. The couplings 406 are one way couplings that couple some of the tubes 410, 412, 414, 416, 418, 420, 422, 424, 426 together. Couplings 408 are couplings that permit easy coupling and uncoupling of tubes 414, 416 and easy coupling and uncoupling of tubes 422, 424. By uncoupling tubes 414, 416 and uncoupling tubes 422, 424, an inverted “J” section of the RF feed is uncoupled. The inverted “J” section comprises two parallel portions and another portion perpendicular to the parallel portions. The vertical portion of the elbow tube 422 is parallel to tube 416. Tube 420 is perpendicular to both tube 416 and the vertical portion of elbow tube 422. Hence, tubes 416, 418, 420, and 422 form an inverted “J” shaped section of the RF feed.

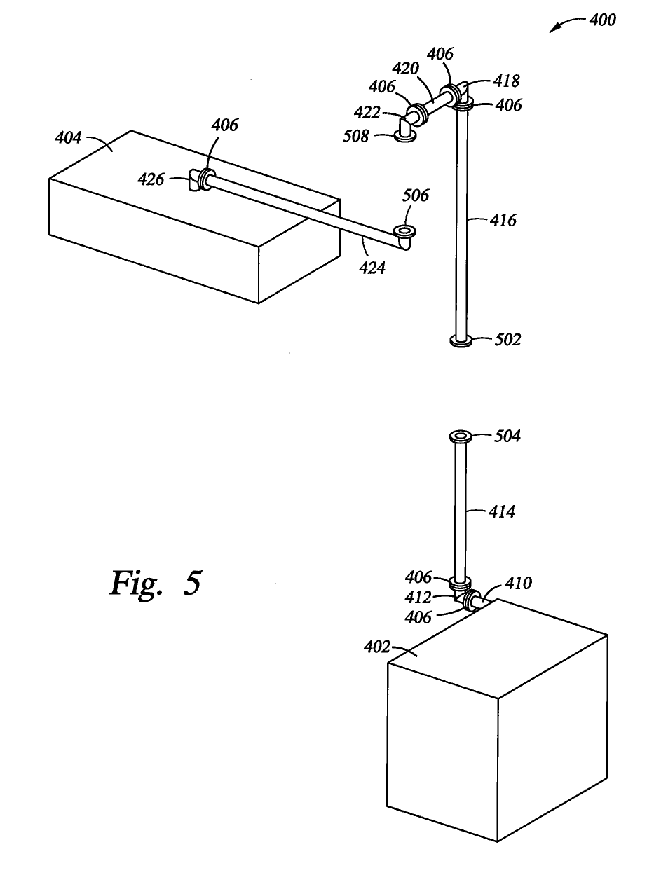

FIG. 5 is a schematic view of the inverted “J” section of the RF feed of FIG. 4 disconnected according to one embodiment of the invention. One end 502 of tube 416 has been uncoupled from one end 504 of tube 414. Additionally, one end 506 of tube 424 has been uncoupled from one end 508 tube 422. The end 508 of elbow tube 422 may be at a different elevation than the end 502 of tube 416. Thus, while tube 416 and the vertical portion of elbow tube 422 are parallel, the ends 502, 508 are at different elevations.

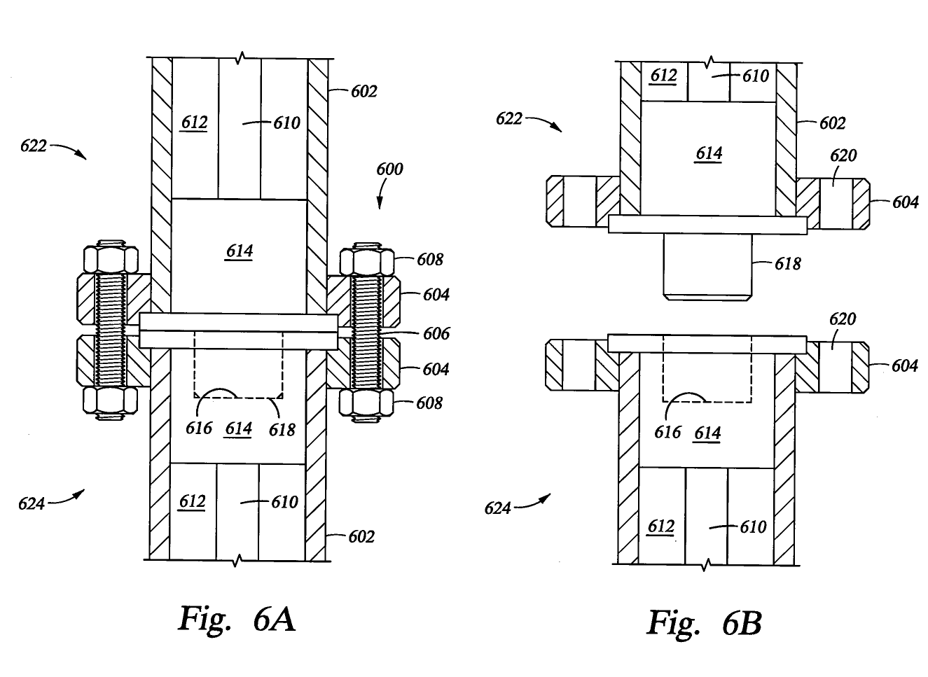

FIG. 6A is a cross sectional view of a coupling 600 for a rigid RF feed according to one embodiment of the invention. In FIG. 6A, an upper section 622 of the RF feed is coupled to a lower section 624 of the RF feed. The upper and lower sections 622, 624 each comprise an outer tube 602 and an inner wire 610. It is to be understood that while the inner wire 610 is described as a wire, any suitable mechanism capable of transmitting RF current there through may be utilized. The outer tube 602 may comprise copper and provides a return path to ground for the RF feed. The outer tube 602 may be separated from the wire 610 by a space 612. In one embodiment, the space 612 may comprise air. The air between the outer tube 602 and the wire 610 acts as a dielectric to prevent loss of power along the RF feed between an RF generator and an RF matching network. The wire 610 may be centered within the space 612 within the outer tube 602.

At the ends of the sections 622, 624, the wires 610 may be coupled with the outer tube 602 by an electrically insulating coupler 614. Thus, the only direct connection between the outer tube 602 and the wire 612 occurs at the electrically insulating coupler 614. The electrically insulating coupler 614 may be disposed at the coupling 600. Flanges 604 may extend from the outer tube 602 at the coupling 600. A fastening mechanism may be disposed through the flanges 604 to couple the upper section 622 to the lower section 624. In one embodiment, the fastening mechanism comprises a bolt 606 and nut 608 assembly.

FIG. 6B is a cross sectional view of the coupling 600 shown in FIG. 6A with the coupling uncoupled. As may be seen in FIG. 6B, a passage 620 may be present within the flange 604 to permit the fastening mechanism to couple the upper section 622 and lower section 624 together. The wires 610 may be coupled together by a male connector 618 extending from the upper section 622 connected into a female receiver 616 disposed in the lower section 624. In one embodiment, the male connector 618 may be disposed in the lower section 624 and the female receiver 618 may be disposed in the upper section 622. The coupling 600 may be used as the couplings 408 and 204b shown in FIGS. 2-5. Both ends of the inverted J section should have the same connection at each end. For example, both ends of the inverted J section may comprise a male connector 618. Alternatively, both ends of the J section may comprise a female receiver 616.

To prevent the wires 610 from uncoupling during the uncoupling of the inverted “J” section from the RF feed, the electrically insulating coupler 614 may be fixedly attached to both the wire 610 and the outer tube 602. In one embodiment, the electrically insulating coupler 614 may be soldered to the wire 610 and to the outer tube 602. Care should be taken when soldering the electrically insulating coupler 614 to the wire 610 and the outer tube 602 to ensure that the soldering locations do not touch. If the soldering locations touch, then the outer tube 602 and the wire 610 will be electrically coupled together and thus, the outer tube 602 may have an active current passing there through. Alternatively, if the outer tube 602 and the wire 610 are electrically coupled together, power may be lost between the RF generator and the RF matching network.

A rigid RF feed having a removable inverted “J” shaped section reduces the amount of power that may be lost between the RF generator and the RF matching network, permits easy coupling and uncoupling of the RF generator to the processing chamber, and shortens the distance between the RF generator and the RF matching network.

While the foregoing is directed to embodiments of the present invention, other and further embodiments of the invention may be devised without departing from the basic scope thereof, and the scope thereof is determined by the claims that follow.

1. A power source for a processing chamber, comprising:
a power generator;
a power input coupled with the processing chamber; and
a rigid feed line coupled between the power generator to the power input.

2. The power source of claim 1, wherein the rigid feed line has at least one inverted J shaped portion.

3. The power source of claim 2, wherein the inverted J shaped portion comprises:
a connector at each end of the J shaped portion, wherein each end has a substantially identical connector.

4. The power source of claim 1, where the rigid feed line comprises:
a plurality of first connectors, wherein the plurality of first connectors comprise removable fasteners; and
a plurality of second connectors, wherein the plurality of second connectors comprise fixed fasteners.

5. The power source of claim 1, wherein the rigid feed line further comprises:
one or more connectors; and
a first copper tube surrounding an electrical transmission wire, wherein the first copper tube is spaced from the electrical transmission wire, and wherein the first copper tube and the electrical transmission wire are coupled together at the one or more connectors by a dielectric material.

6. The power source of claim 5, wherein the first copper tube and the electrical transmission wire are coupled together only at each connector.

7. The power source of claim 1, wherein the rigid feed line comprises two parallel portions of unequal length coupled together by a portion perpendicular to the two parallel portions.

8. A plasma apparatus, comprising:
a processing chamber having a lid assembly coupled thereto;
an RF matching network disposed on the lid assembly;
an RF generator disposed below the RF matching network; and
a rigid RF feed line coupled between the RF matching network and the RF generator.

9. The apparatus of claim 8, wherein the rigid RF feed line comprises at least one inverted J shaped portion.

10. The apparatus of claim 9, wherein the inverted J shaped portion comprises:
a connector at each end of the J shaped portion, wherein each end has an identical connector.

11. The apparatus of claim 10, further comprising a platform assembly at a level of about one half the height of the processing chamber, wherein at least one end of the J shaped portion is at a substantial height of the platform assembly.

12. The apparatus of claim 11, wherein at least one fixed connection of the J shaped portion is disposed about 5 inches above the platform assembly.

13. The apparatus of claim 11, wherein the RF generator is disposed below the platform assembly.

14. The apparatus of claim 8, wherein the rigid RF feed line further comprises:
one or more connectors; and
a first copper tube surrounding an electrical transmission wire, wherein the first copper tube is spaced from the electrical transmission wire, and wherein the first copper tube and the electrical transmission wire are coupled together at the one or more connectors by a dielectric material.

15. The apparatus of claim 14, wherein the first copper tube and the electrical transmission wire are coupled together only at each connector.

16. The apparatus of claim 8, wherein the apparatus is a plasma enhanced chemical vapor deposition apparatus.

17. The apparatus of claim 8, wherein the RF feed line comprises two parallel portions of unequal length coupled together by a portion perpendicular to the two parallel portions.

18. The apparatus of claim 8, where the RF feed line comprises:
a plurality of first connectors, wherein the plurality of first connectors comprise removable fasteners; and
a plurality of second connectors, wherein the plurality of second connectors comprise fixed fasteners.

19. A method of connecting a power supply to a processing chamber, comprising:
lowering a rigid RF feed line into contact with both a power supply and a matching network, the RF feed comprising two substantially parallel portions and a portion substantially perpendicular to the two substantially parallel portions;
connecting a first end of the rigid RF feed to a power supply; and
connecting a second end of the rigid RF feed to a matching network.

20. The method of claim 19, wherein the two substantially parallel portions have different lengths and wherein the rigid RF feed line has a substantially inverted J shape.
